(19) United States
(12) Patent Application Publication
(10) Pub. No.: US 2024/0196605 A1
(43) Pub. Date: Jun. 13, 2024

(54) SEMICONDUCTOR PROCESS FOR SOLVING CONTACT PIPING DEFECT

(71) Applicant: Powerchip Semiconductor Manufacturing Corporation, HSINCHU (TW)

(72) Inventors: Hui-Chin Huang, Hsinchu City (TW); Hung-Ju Chien, Hsinchu County (TW); Yu-Mei Liao, Hsinchu County (TW); Kai-Yao Shih, Hsinchu City (TW)

(73) Assignee: Powerchip Semiconductor Manufacturing Corporation, HSINCHU (TW)

(21) Appl. No.: 18/134,029

(22) Filed: Apr. 12, 2023

(30) Foreign Application Priority Data
Dec. 8, 2022 (TW) 111147208

(51) Int. Cl. H10B 41/35

(52) U.S. Cl. CPC H10B 41/35

(57) ABSTRACT

A semiconductor process for solving contact piping defect is provided in the present invention, including forming gates on a substrate, forming SiN spacers on sidewalls of the gates and the substrate is exposed from the SiN spacers between adjacent gates, performing an epitaxy process to form Si-based sacrificial layers on the gates and the exposed doped areas, and performing a first etchback process using phosphoric acid to pull back the SiN spacers, and the first etchback process removes the Si-based sacrificial layers.

### BACKGROUND OF THE INVENTION

### 1. Field of the Invention

The present invention relates generally to a semiconductor process, and more specifically, to a semiconductor process for solving contact piping defect.

### 2. Description of the Prior Art

Modern consumer electronics face design requirement and challenge in high-mix low-volume (HMLV) product designs, and low-power embedded non-volatile memory (eNVM) technology, such as eFlash, can meet the market needs of this kind. With booming growth in products and applications like microcontroller unit (MCU), system-on-chip (SoC), internet of things (IoT), automotive electronics, industrial control and application specific integrated circuit (ASIC), market has huge demand for eNVM.

However, eNVM process will encounter many problems when integrated in logic process, causing dimension scaling of devices more and more difficult. For example, gaps between gates of eNVM become very small in the progress of dimension scaling. Plus if the gates have thick spacers, it may easily form voids in the interlayer dielectrics (ILD) filled therebetween, thereby causing piping defect when forming contacts in the interlayer dielectrics later, further causing the resulting contacts short-circuited or leaking. Although this problem may be solved by using other dielectrics with good gap-filling capability (ex. spin-on-dielectrics, SOD), the dielectrics available in logic process is very limited. In addition, approach of pull-back process is adopted in conventional skill to widen the gap opening and reduce the height of the spacers, but this approach tends to damage active areas and shallow trench isolations (STIs) already formed in the substrate, and may increase the width and profile of metal silicide to be formed in later process, impacting electrical properties of the device.

### SUMMARY OF THE INVENTION

In light of the aforementioned issues encountered in conventional skill, the present invention hereby provides a novel semiconductor process, featuring the Si-based sacrificial layer formed before the pull-back process of spacers, to avoid the damage of gates and substrate in the pull-back process.

The objective of present invention is to provide a semiconductor process for solving contact piping defect, including steps of: forming multiple gates on a substrate; forming SiN spacers on sidewalls of the gates, wherein the substrate is exposed from gaps between the SiN spacers of adjacent gates; performing an ion implantation process to form doped regions exposed from the gaps; performing an epitaxy process to form Si-based sacrificial layers on the gates and the exposed substrate; and performing an first etchback process using phosphoric acid to pull back the SiN spacers, and the first etchback process removes the Si-based sacrificial layers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 9 are schematic cross-sectional views illustrating a flow of a semiconductor process for solving contact piping defects in accordance with one embodiment of present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon (Si), germanium (Ge), gallium arsenide (GaAs), indium phosphide (InP), etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

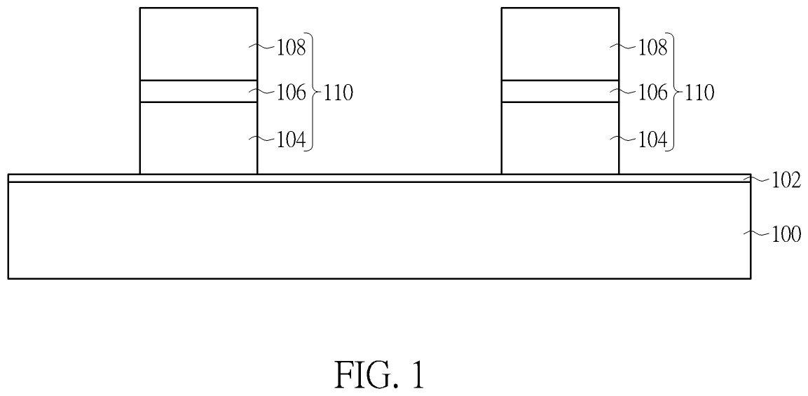

FIG. 1 to FIG. 9 will now be referred sequentially hereinafter to describe the semiconductor process of present invention, wherein relative positions and connections between components in vertical direction in the process are illustrated by the manner of cross-sections, and two gates are exemplified in the figures to provide readers a better understanding of the progress and relation of the components therein in the process. However, please note that in actual structure, semiconductor device may be consisted of different structures depending on where the cross-sections are taken, for example, whether there are active areas or shallow trench isolations (STIs) in the substrate and if there are metal silicide formed thereon, and gates may be arranged, but not limited, in strip form.

Please refer to FIG. 1. In the beginning of process, a semiconductor substrate 100 is provided as a basis for forming the semiconductor device of present invention. The material of substrate 100 is preferably silicon (Si) substrate, ex. a p-type doped silicon substrate, but other substrate containing silicon may also be adopted, including group III-V GaN-on-silicon substrate or silicon-on-insulator (SOI) substrate, etc., or substrate of other doping type, but not limited thereto. A tunnel oxide layer 102 is formed on the surface of semiconductor substrate 100, ex. silicon oxide, which may be formed through thermal oxidation or deposition. Multiple gates 110 are formed on the tunnel oxide layer 102. In the embodiment of present invention, each gate 110 may include a floating gate 104, an inter-gate dielectric layer 106 and a control gate 108 sequentially from the substrate 100, wherein the material of floating gate 104 and control gate 108 may be polysilicon, and inter-gate dielectric layer 106 may be silicon oxide-silicon nitride-silicon oxide (ONO) multilayer structure. Gates 110 may be formed through depositing the aforementioned layers and then performing photolithography process to patterning them, wherein the deposition method may include but not be limited to LPCVD, CVD or PVD, etc. In the operation of flash memory, control gate 108 will be applied with voltage through word lines to control the storage or release of charges in the floating gate 104 below. The inter-gate dielectric layer 106 isolates the electrical connection between the floating gate 104 and the control gate 108, while the tunnel oxide layer 102 may allow charges tunneling into or out of the floating gate 104. Whether the quantity of charges stored in the floating gate 104 exceeds threshold determines its storage state. In another embodiment of present invention, each gate 110 may be a select gate in flash memory, and the control gate 108 connects the floating gate 104 through an opening of the inter-gate dielectric layer 106 (not shown in FIGS). The type of flash memory in the embodiment may include but not be limited to NAND flash or NOR flash, and outer side of the gate 110 may be further connected with other gates having different functionalities.

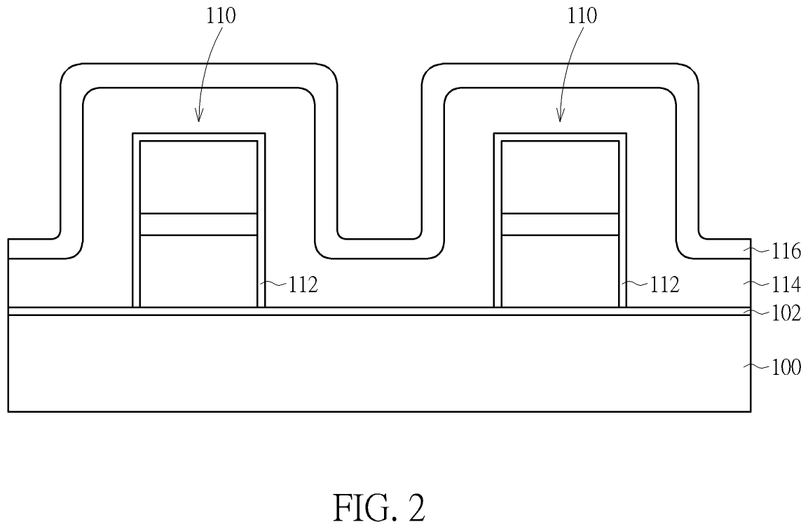

Please refer to FIG. 2. After gates 110 are formed, an oxidation process is then performed to form thin oxide layers 112 on the surfaces and sidewalls of gates 110 in order to protect the gates 110 and make them isolated from outsides. In addition, a thin nitride layer may be further formed on the oxide layer 112 to constitute a silicon oxide-silicon nitride-silicon oxide multilayer structure. After oxide layers 112 are formed, a conformal silicon nitride spacer layer 114 and a tetraethoxysilane (TEOS) spacer layer 116 are then formed sequentially on the substrate 100 and gates 110, which may be formed through CVD or ALD, etc. The silicon nitride spacer layer 114 and tetraethoxysilane (TEOS) spacer layer 116 will be transformed into spacers at two sides of gates 110 in later process, wherein the thickness of silicon nitride spacer layer 114 is larger than the thickness of TEOS layer 116.

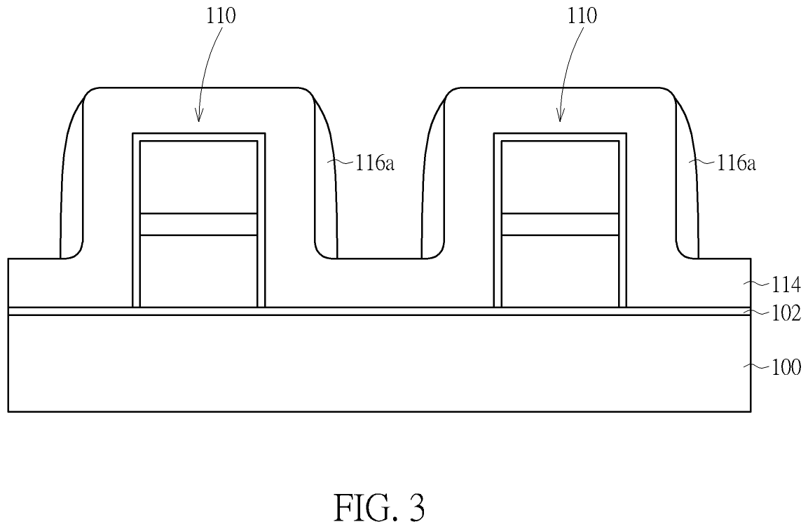

Please refer to FIG. 3. After the silicon nitride spacer layer 114 and TEOS layer 116 are formed, an etchback process is then performed to remove the TEOS layer 116 of a predetermined vertical thickness, thereby forming the TEOS spacers 116a. The TEOS spacers 116a are on the sidewalls of silicon nitride spacer layer 114, which may control the profile of doped regions (ex. source and drain) to be formed in the substrate 100 in later process.

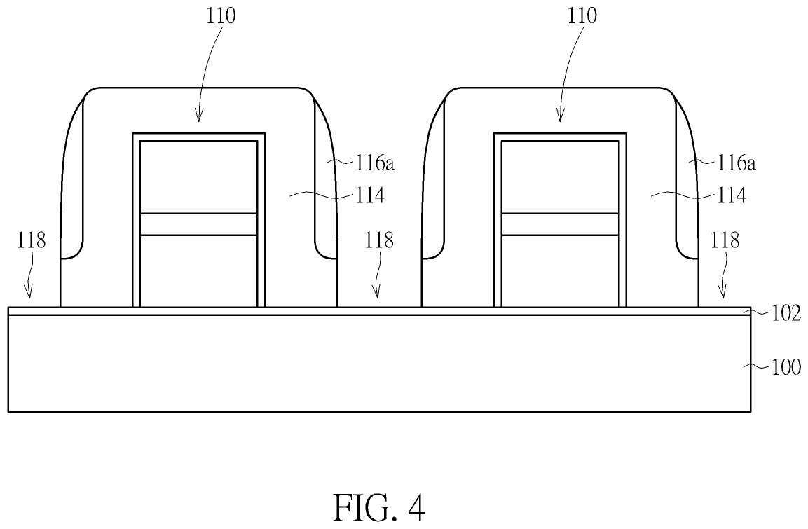

Please refer to FIG. 4. After the TEOS spacers 116a are formed, a photolithography process is then performed to remove the silicon nitride spacer layer 114 between adjacent gates 110 on the substrate 100, thereby exposing regions 118 of the substrate 100 predetermined for forming the doped regions, wherein TEOS spacers 116a may function as an etch mask in this step to achieve self-alignment and etching of the silicon nitride spacer layer 114. Besides, the tunnel oxide layer 102 on the regions 118 of substrate 100 predetermined for forming doped regions may be removed in this step. In actual implementation, the gap between gates 110 is very small, which may easily form voids since the interlayer dielectric layer (ILD) to be formed later is difficult to be filled therein, thereby forming piping defect after contacts are formed. This is the problem the present invention dedicates to solve.

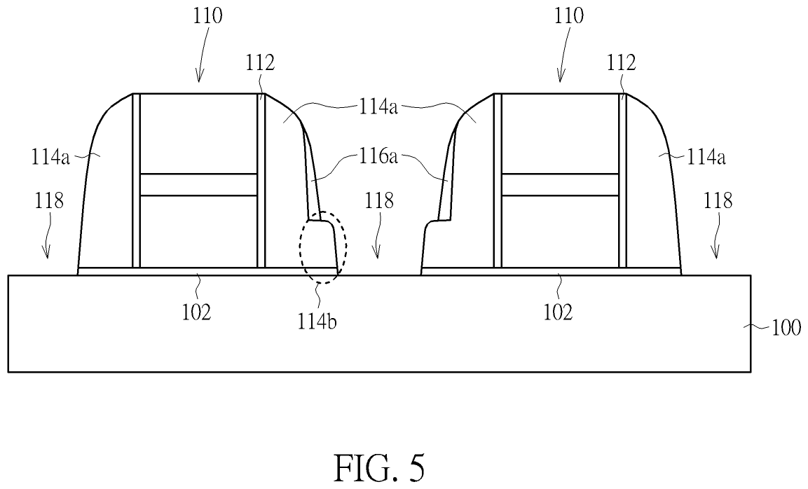

Please refer to FIG. 5. After the photolithography process, another etchback process is then performed to remove the silicon nitride spacer layer 114 of a predetermined vertical thickness, thereby forming the silicon nitride spacers 114a at two sides of each gate 110. In this step, the TEOS spacers 116a once on the silicon nitride spacer layer 114 are also affected by this etchback process and are partially removed and their thickness are reduced, so that eventually adjacent silicon nitride spacers 114a will be provided with extensions 114b extending toward each other and exceed horizontally beyond the TEOS spacers 116a above. In other aspect, the etchback process would have higher etching potent at outer side of the gate 110 since there is an open space in comparison to the inner side of the gate 110, and the TEOS spacers 116a on the silicon nitride spacers 114a at outer side of the gate 110 will be completely removed, eventually the silicon nitride spacers 114a formed at outer sides would not have these extensions 114b. In addition, the oxide layer 112 on the top surface of gate 110 is also removed after this etchback process, exposing Si-based surface. Tunnel oxide layer 102 on regions 118 of the substrate 100 predetermined for forming doped regions may also be completely removed in this step. At last, the resulting silicon nitride spacers 114a in this step may define entire gate structure and regions for forming metal silicide thereon and at two sides later.

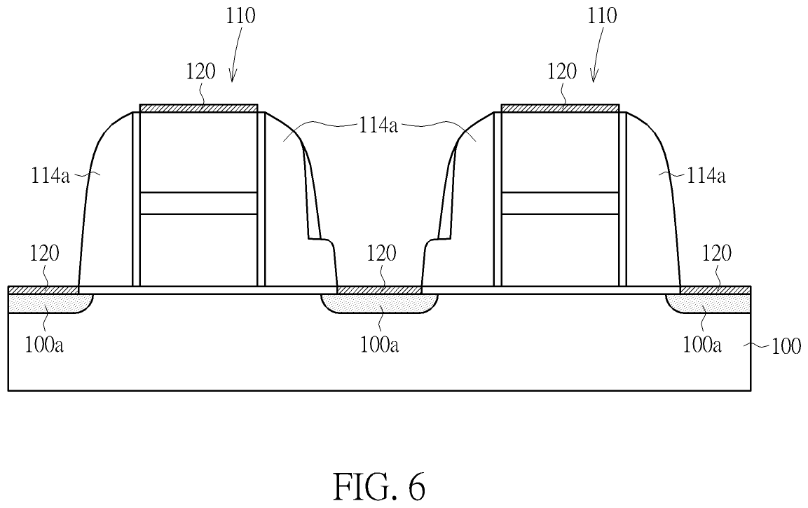

Please refer to FIG. 6. After the silicon nitride spacers 114a are formed, an ion implantation process and an annealing step are performed to form doped regions 100a in the substrate 100 as sources and drain of the memory devices. Take P-type doped silicon substrate as an example, N-type ions may be heavily doped in regions 118 of the substrate 100 predetermined for forming the doped regions to form N+ doped regions 100a. After the doped regions 100a are formed, thin Si-based sacrificial layers 120 are formed on exposed substrate 100 and top surfaces of gates 110, which may be formed on Si-based surfaces through epitaxial growth in MOCVD process. In the embodiment of present invention, the function of Si-based sacrificial layers 120 is to prevent additional etchback process later for the silicon nitride spacers 114a damaging exposed top surfaces of gates 110 as well as active areas or STIs in the substrate 100.

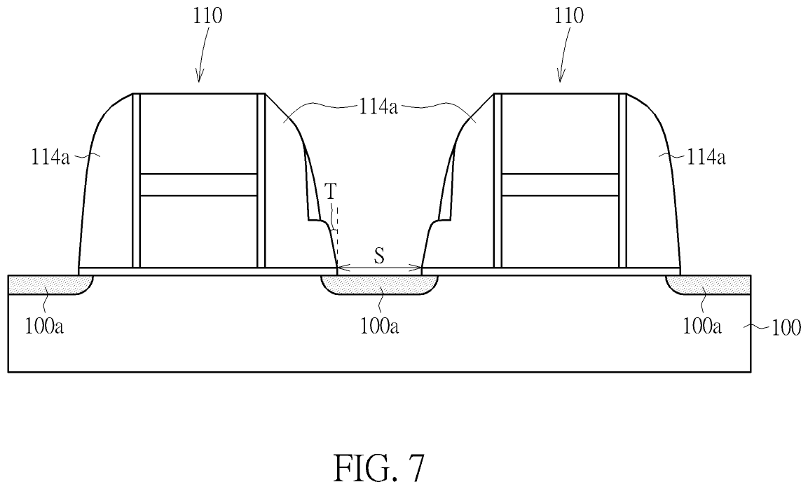

Please refer to FIG. 7. After Si-based sacrificial layers 120 are formed, an etchback process is then performed using phosphoric acid to pull back the silicon nitride spacers 114a. This etch back process may increase angle of inclination T of the silicon nitride spacers 114a at inner sides of the gates 110, make the sidewalls smoother, especially for the extensions 114b of silicon nitride spacers 114a, so that the opening of gap S between gates 110 may be widen and their aspect ratio may be reduced, and the interlayer dielectric layer formed later may be filled therein easily, preventing the formation of voids and contact piping defect. In conventional skill, this etchback process would affect exposed gates 110 and substrate 100, damaging the active areas or STIs in the substrate 100 or the width and profile of metal silicide formed later will be unexpectedly increased, which further impact electrical property of the devices. Accordingly, in the embodiment of present invention, phosphoric acid (H₃PO₄) etchant is adopted specifically in this etchback process to prevent the damage of silicon oxide based STIs, and Si-based sacrificial layers 120 may block the exposed gates 110 and substrate 100, protecting them from the etchback process. In the embodiment of present invention, the thickness of Si-based sacrificial layers 120 is preferably controlled so that they may be completely removed just right in the etchback process. For example, if the dimension of silicon nitride spacers 114a pulled back in this etchback process is 3-5 nm, the thickness of Si-based sacrificial layer 120 is approximately 10 nm.

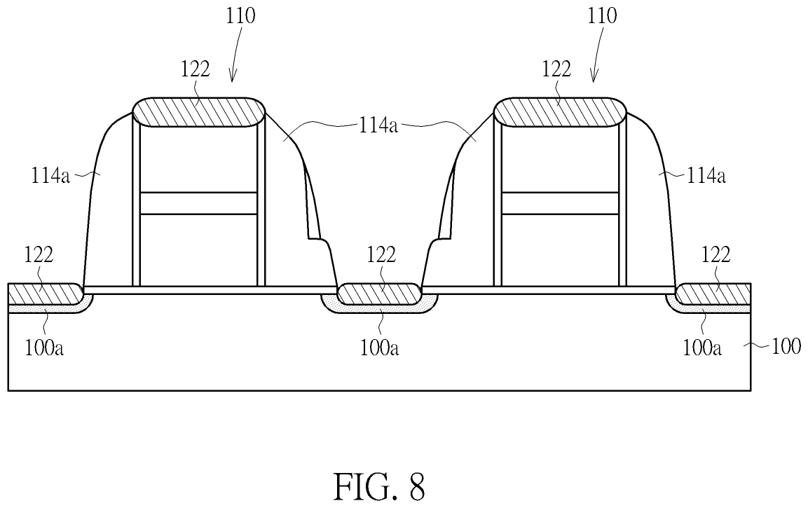

Please refer to FIG. 8. After the etchback process is performed for the silicon nitride spacers 114a, a metal silicide process is then performed to form metal silicide layers 122, ex. nickel silicide, on top surfaces of the gates 110 and on those doped regions 100a, to reduce contact resistance after those components are connected with contacts. This metal silicide process may include first forming a self-aligned silicide block layer (SAB, not shown) to cover those substrate regions not for forming metal silicide, and metal silicide process is then performed to transform the parts of gates 110 and doped regions exposed from the SAB layer into metal silicide layer 122. The Si-based sacrificial layers 120 not removed in previous processes may also be transformed into metal silicide layer 122 in this process.

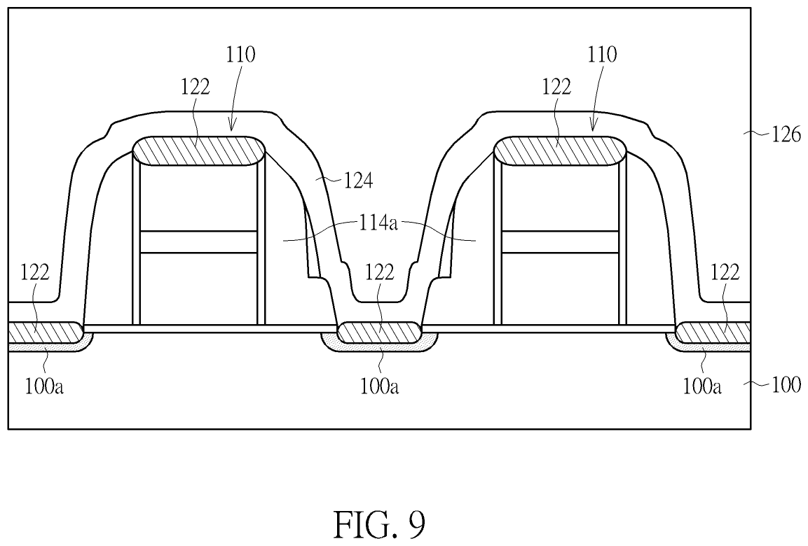

Please refer to FIG. 9. After metal silicide layers 122 are formed, an etch stop layer 124, ex. silicon nitride layer, is then formed on the substrate 100 to conformally cover the metal silicide layers 122, gates 110, silicon nitride spacers 114a, etc., functioning as an etch stop layer for forming contacts later. After the etch stop layer 124 is formed, a thick interlayer dielectric layer 126 is then covered on entire substrate surface, ex. phosphosilicate glass (PSG), borophosphosilicate glass (BPSG) or low-k dielectric material, which may be formed using deposition method like CVD, PECVD or PVD. In the embodiment of present invention, since silicon nitride spacers 114a are subject to additional etchback treatment to improve their sidewall profiles, voids are not easily formed in the interlayer dielectric layer 126 filled in the gaps between gates 110, contact piping issue in conventional skill is therefore solved. After the interlayer dielectric layer 126 is formed, contacts may then be formed in the interlayer dielectric layer 126 to connect those metal silicide layers 122. Since this process is conventional, relevant details and features will not be described and shown in specification and drawing.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor process for solving contact piping defect, comprising:
forming multiple gates on a substrate;
forming silicon nitride spacers on sidewalls of said gates, wherein said substrate is exposed from gaps between said silicon nitride spacers on adjacent said gates;
performing an ion implantation process to form doped regions in said substrate exposed from said gaps;
performing an epitaxy process to form silicon-based sacrificial layers on said gates and exposed said doped regions; and
performing a first etchback process using phosphoric acid to pull back said silicon nitride spacers, and said first etchback process removes said silicon-based sacrificial layers.

2. The semiconductor process for solving contact piping defect of claim 1, further comprising:
forming metal silicide layers on said gates and said doped regions after said first etchback process;
forming an etch stop layer on said metal silicide layers, said silicon nitride spacers and said substrate;
forming an interlayer dielectric layer on said etch stop layers; and
forming contacts connecting said metal silicide layers in said interlayer dielectric layer.

3. The semiconductor process for solving contact piping defect of claim 2, wherein steps of forming said metal silicide layers comprises:
forming silicide block layers on said substrate to cover regions not for forming metal silicide; and
performing a metal silicide process to transform parts of said gates and said doped regions exposed from said silicide block layers into said metal silicide layers.

4. The semiconductor process for solving contact piping defect of claim 1, wherein steps of forming said silicon nitride spacers comprises:
forming a conformal silicon nitride spacer layer and a tetraethoxysilane (TEOS) layer sequentially on said gates and said substrate;
performing a second etchback process to remove parts of said TEOS layer, so as to form said TEOS spacers on said silicon nitride spacer layer;
performing a photolithography process to remove said silicon nitride spacer layer between adjacent said gates on said substrate, so as to expose parts of said substrate predetermined for forming said doped regions; and
performing a third etchback process to remove remaining said silicon nitride spacer layer, so as to form said silicon nitride spacers on sidewalls of said gates.

5. The semiconductor process for solving contact piping defect of claim 4, wherein said third etchback process also removes said TEOS spacers, so as to form extensions of said silicon nitride spacers between adjacent gates, and said extensions extend horizontally beyond said TEOS spacers thereon.

6. The semiconductor process for solving contact piping defect of claim 5, wherein said first etchback process makes angle of inclination of said extensions of said silicon nitride spacers larger and smoother.

7. The semiconductor process for solving contact piping defect of claim 1, further comprising performing an oxidation process before forming said silicon nitride spacers to form oxide layers on sidewalls of said gates, and said silicon nitride spacers are then formed on surfaces of said oxide layers.

8. The semiconductor process for solving contact piping defect of claim 1, wherein each of said gates comprises a floating gate, a silicon oxide-silicon nitride-silicon oxide (ONO) multilayer structure and a control gate sequentially from said substrate.

9. The semiconductor process for solving contact piping defect of claim 8, wherein said gates are select gates in an embedded flash memory, and in each of said select gates, said control gate connects said floating gate through an opening of said multilayer structure.
